(19) United States
(12) Patent Application Publication
(10) Pub. No.: US 2024/0079349 A1
(43) Pub. Date: Mar. 7, 2024

(54) SEMICONDUCTOR PACKAGE

(71) Applicant: Samsung Electronics Co., Ltd., Suwon-si (KR)

(72) Inventors: Yanggyoo Jung, Suwon-si (KR); Younglyong Kim, Suwon-si (KR); Seungbin Baek, Suwon-si (KR)

(21) Appl. No.: 18/334,578

(22) Filed: Jun. 14, 2023

(30) Foreign Application Priority Data
Sep. 1, 2022 (KR) 10-2022-0111017

(51) Int. Cl. H01L 23/00; H01L 23/053; H01L 23/36; H01L 23/538; H01L 25/065; H01L 25/16

(52) U.S. Cl. CPC H01L 23/562; H01L 23/053; H01L 23/36; H01L 23/5385; H01L 24/32; H01L 25/0655; H01L 25/16; H01L 24/16; H01L 24/73; H01L 2224/16227; H01L 2224/32225; H01L 2224/32245; H01L 2224/73204

(57) ABSTRACT

A semiconductor package is provided to include a package substrate, a plurality of semiconductor chips mounted on the package substrate, an interposer arranged between the package substrate and the plurality of semiconductor chips, a plurality of passive elements mounted on the package substrate and spaced apart from the interposer, a first stiffener positioned on the package substrate and including a first hole accommodating the interposer and a second hole accommodating the plurality of passive elements, and a second stiffener positioned on the first stiffener and including a third hole communicating with the first hole. The first stiffener has a first coefficient of thermal expansion, and the second stiffener has a second coefficient of thermal expansion different from the first coefficient of thermal expansion.

### CROSS-REFERENCE TO RELATED APPLICATION

This application is based on and claims priority under 35 U.S.C. § 119 to Korean Patent Application No. 10-2022-0111017, filed on Sep. 1, 2022, in the Korean Intellectual Property Office, the disclosure of which is incorporated by reference herein in its entirety.

### BACKGROUND

The inventive concept relates to a semiconductor package, and more particularly, to a semiconductor package including an underfill.

The semiconductor package is implemented in a form suitable for using a semiconductor chip in electronic products. In general, a conventional semiconductor package has a configuration that a semiconductor chip is mounted on a printed circuit board and electrically connected to the printed circuit board by bonding wires or bumps. Recently, the size of the semiconductor package tends to increase according to the high performance of the semiconductor package. In a large-sized semiconductor package, a stiffener has been widely used in semiconductor packages for controlling warpage defects caused by differences of thermal expansion coefficients among individual components of the semiconductor package.

### SUMMARY

The inventive concept provides a semiconductor package that prevents underfills from flowing outwards and making contact with passive elements.

The inventive concept provides a semiconductor package for reducing the warpage defects.

In addition, the problems to be solved by the inventive concept are not limited to the above-described problems, and some other problems are clearly understood by one of ordinary skill in the art from the following descriptions hereinafter.

According to an aspect of the inventive concept, there is provided a semiconductor package including a package substrate, a plurality of semiconductor chips mounted on the package substrate, an interposer arranged between the package substrate and the plurality of semiconductor chips, a plurality of passive elements mounted on the package substrate and spaced apart from the interposer, a first stiffener positioned on the package substrate and including a first hole accommodating the interposer and a second hole accommodating the plurality of passive elements, and a second stiffener positioned on the first stiffener and including a third hole communicating with the first hole. The first stiffener may have a first coefficient of thermal expansion, and the second stiffener may have a second coefficient of thermal expansion different from the first coefficient of thermal expansion.

According to another aspect of the inventive concept, there is provided a semiconductor package including a package substrate, a plurality of semiconductor chips mounted on the package substrate, an interposer arranged between the package substrate and the plurality of semiconductor chips, a plurality of passive elements mounted on the package substrate and spaced apart from the interposer, a first stiffener positioned on the package substrate and including a first hole accommodating the interposer and a first concave portion surrounding the plurality of passive elements, and a second stiffener positioned on the first stiffener and including a third hole communicating with the first hole. The first stiffener may have a first coefficient of thermal expansion, and the second stiffener may have a second coefficient of thermal expansion different from the first coefficient of thermal expansion.

According to another aspect of the inventive concept, there is provided a semiconductor package including a package substrate, a plurality of semiconductor chips mounted on the package substrate, an interposer arranged between the package substrate and the plurality of semiconductor chips, a plurality of passive elements including a first passive element spaced apart from the interposer in a first horizontal direction and a second passive element spaced apart in a second horizontal direction, a first stiffener positioned on the package substrate and including a first hole accommodating the interposer and a first concave portion surrounding the plurality of passive elements, a second stiffener positioned on the first stiffener and including a third hole communicating with the first hole, a first plate positioned on the second stiffener and covering an upper surface of the second stiffener and the third hole, a first underfill layer positioned between the package substrate and the interposer and in the first hole of the first stiffener, and a thermal interface material layer arranged between the first plate and the plurality of semiconductor chips. The first stiffener may have a first coefficient of thermal expansion smaller than that of the package substrate, the second stiffener may have a second coefficient of thermal expansion smaller than the first coefficient of thermal expansion, the first plate may have a third coefficient of thermal expansion smaller than the second coefficient of thermal expansion, the first hole may include a sidewall arranged between the interposer and the plurality of passive elements, the first concave portion may include sidewalls spaced apart from sidewalls of the plurality of passive elements and an upper surface spaced apart from upper surfaces of the plurality of passive elements, and a sum of heights of the first stiffener and the second stiffener may be about 500 μm to about 4000 μm.

### BRIEF DESCRIPTION OF THE DRAWINGS

Embodiments will be more clearly understood from the following detailed description taken in conjunction with the accompanying drawings in which:

FIG. 1 is a plan view schematically illustrating a semiconductor package, according to an embodiment;

FIG. 2 is a plan view schematically illustrating a first stiffener of the semiconductor package in FIG. 1;

FIG. 3 is a plan view schematically illustrating a second stiffener of the semiconductor package in FIG. 1;

FIG. 4 is a cross-sectional view schematically illustrating the semiconductor package in FIG. 1;

FIG. 5 is a cross-sectional view schematically illustrating a semiconductor package according an embodiment;

FIG. 6 is a cross-sectional view schematically illustrating a semiconductor package according to an embodiment;

FIG. 7 is a plan view schematically illustrating a semiconductor package according to anther embodiment;

FIG. 8 is a cross-sectional view schematically illustrating the semiconductor package in FIG. 7;

FIG. 9 is a cross-sectional view schematically illustrating a semiconductor package according to an embodiment;

FIG. 10 is a cross-sectional view schematically illustrating a semiconductor package according to an embodiment;

FIG. 11 is a plan view schematically illustrating a semiconductor package according to an embodiment;

FIG. 12 is a plan view schematically illustrating a first stiffener of the semiconductor package in FIG. 11;

FIG. 13 is a cross-sectional view schematically illustrating the semiconductor package in FIG. 11;

FIG. 14 is a cross-sectional view schematically illustrating a semiconductor package according to an embodiment;

FIG. 15 is a cross-sectional view schematically illustrating a semiconductor package according to an embodiment;

FIG. 16 is a plan view schematically illustrating a semiconductor package according to an embodiment;

FIG. 17 is a cross-sectional view schematically illustrating a semiconductor package according to an embodiment;

FIG. 18 is a cross-sectional view schematically illustrating a semiconductor package according to an embodiment; and

FIGS. 19A to 19G are cross-sectional views sequentially illustrating a method of manufacturing a semiconductor package according to an embodiment.

### DETAILED DESCRIPTION OF THE EMBODIMENTS

Since embodiments of the inventive concept may have various changes and forms, some specific embodiments will be illustrated in the drawings and described in detail. However, this is not intended to limit the present embodiments to a specific disclosed form.

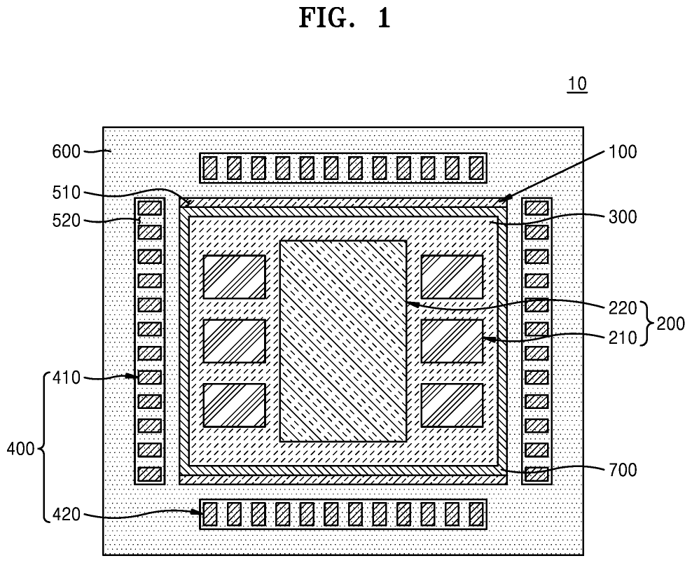

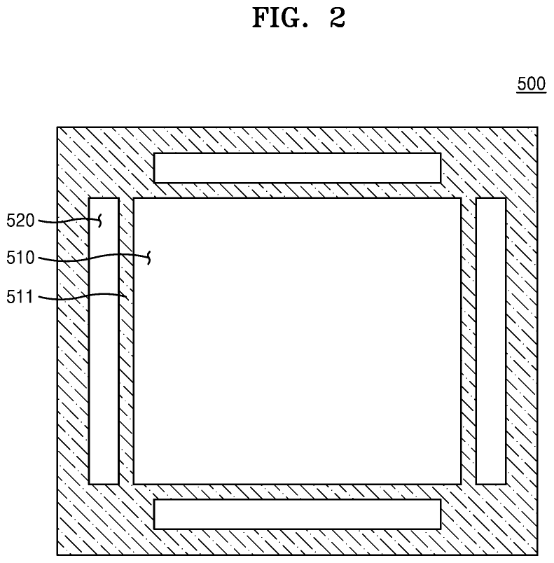

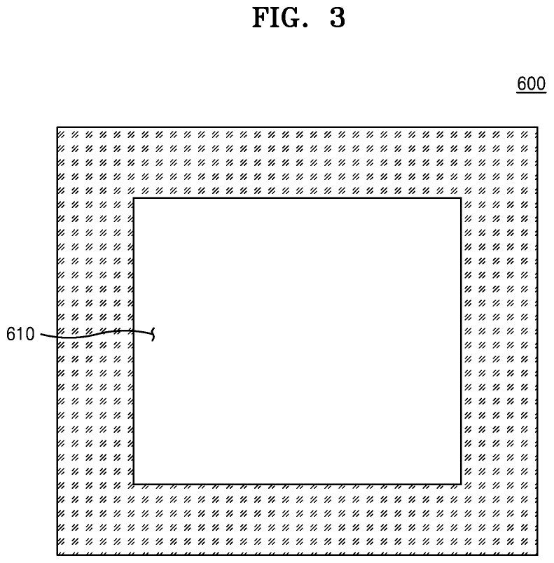

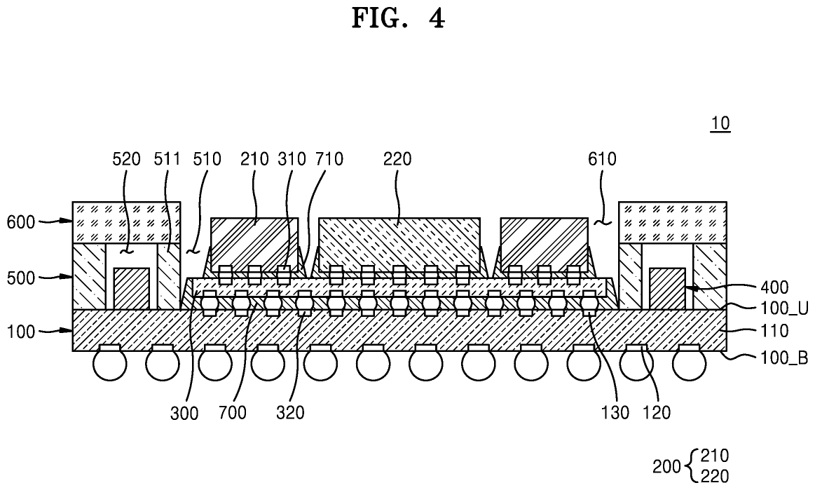

FIG. 1 is a plan view schematically illustrating a semiconductor package, according to an embodiment. FIG. 2 is a plan view schematically illustrating a first stiffener of the semiconductor package in FIG. 1. FIG. 3 is a plan view schematically illustrating a second stiffener of the semiconductor package in FIG. 1. FIG. 4 is a cross-sectional view schematically illustrating the semiconductor package in FIG. 1.

Referring to FIGS. 1 to 4, a semiconductor package 10 may include a package substrate 100, a plurality of semiconductor chips 200, an interposer 300, a plurality of passive elements 400, a first stiffener 500, a second stiffener 600, and a first underfill layer 700.

A package substrate 100 of the semiconductor package 10 may have a flat plate shape or a panel shape. The package substrate 100 may include an upper surface 100_U and a bottom surface 100_B opposite to each other, and the upper surface 100_U and the bottom surface 100_B may be shaped into a plain

The package substrate 100 may be, for example, a printed circuit board (PCB). The package substrate 100 may include a core insulating layer 110, a plurality of upper contact pads 130, and a plurality of lower contact pads 120.

The core insulating layer 110 may include at least one material selected from a phenol resin, an epoxy resin, and a polyimide. For example, the core insulating layer 110 may include at least one material selected from polyimide, flame retardant 4 (FR-4), tetrafunctional epoxy, polyphenylene ether, epoxy/polyphenylene oxide, bismaleimide triazine (BT), thermount, cyanate ester, and a liquid crystal polymer.

The plurality of upper contact pads 130 may be arranged on the upper surface 100_U of the core insulating layer 110, and the plurality of lower contact pads 120 may be arranged on the bottom surface 100_B of the core insulating layer 110. Inner wirings may be provided in the core insulating layer 110 and may electrically connect the upper contact pads 130 and the lower contact pads 120. For example, the upper contact pads 130 and the lower contact pads 120 may include a metal, such as copper (Cu), aluminum (Al), tungsten (W), titanium (Ti), tantalum (Ta), and indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or a metal alloy thereof.

A plurality of external contact terminals may be attached to the lower contact pads 120 of the package substrate 100. The external contact terminals may be configured to electrically and physically connect the package substrate 100 to an external device. The external contact terminals may be formed from, for example, solder balls or solder bumps.

The plurality of semiconductor chips 200 of the semiconductor package 10 may be mounted on the package substrate 100. The plurality of semiconductor chips 200 may be spaced apart from the interposer 300. The plurality of semiconductor chips 200 may include different types of semiconductor chips. The plurality of semiconductor chips 200 may be electrically connected to each other by the interposer 300 and/or the package substrate 100. The plurality of semiconductor chips 200 may include a memory chip, a logic chip, a system on chip (SOC), a power management integrated circuit (PMIC) chip, and a radio frequency integrated circuit (RFIC) chip, etc. The memory chip may include a dynamic random access memory (DRAM) chip, an static random access memory (SRAM) chip, a magnetic random access memory (MRAM) chip, a NAND flash memory chip, and/or a high bandwidth memory (HBM) chip. The logic chip may include an application processor (AP), a micro-processor, a central processing unit (CPU), a controller, and/or an application specific integrated circuit (ASIC). For example, the SOC may include at least two electric circuits among a logic circuit, a memory circuit, a digital integrated circuit (IC), a radio frequency integrated circuit (RFIC), and an input/output circuit.

The plurality of semiconductor chips 200 may include one or more first semiconductor chips 210 and one or more second semiconductor chips 220. The first semiconductor chip 210 may be a logic chip, and the second semiconductor chip 220 may be a memory chip. For example, the first semiconductor chip 210 may include an ASIC, and the second semiconductor chip 220 may include an HBM chip.

The first semiconductor chip 210 may include a first semiconductor substrate and a first chip pad. The first semiconductor substrate may include upper and lower surfaces opposite to each other. A lower surface of the first semiconductor substrate may be an active surface of the first semiconductor substrate, and an upper surface of the first semiconductor substrate may be an inactive surface of the first semiconductor substrate. The first semiconductor substrate may be formed from a semiconductor wafer. The first semiconductor substrate may include, for example, silicon (Si). A semiconductor device layer including individual devices may be provided on the active surface of the first semiconductor substrate. The individual devices may include, for example, a transistor. The first chip pad may be provided on a lower surface of the first semiconductor chip. The first chip pad may include a conductive material such as copper and may be electrically connected to the individual elements of the first semiconductor chip 210.

The second semiconductor chip 220 may include a second semiconductor substrate and a second chip pad. The second semiconductor substrate may include upper and lower surfaces opposite to each other. A lower surface of the second semiconductor substrate may be an active surface of the second semiconductor substrate, and an upper surface of the second semiconductor substrate may be an inactive surface of the second semiconductor substrate. The second semiconductor substrate may be formed from a semiconductor wafer. The second semiconductor substrate may include, for example, silicon (Si). A semiconductor device layer including individual devices may be provided on the active surface of the second semiconductor substrate. The individual devices may include, for example, a transistor. The second chip pad may be provided on a lower surface of the second semiconductor chip. The second chip pad may include a conductive material, such as copper, and may be electrically connected to the individual elements of the second semiconductor chip 220.

The interposer 300 of the semiconductor package 10 may be positioned between the package substrate 100 and the plurality of semiconductor chips 200, and may be configured to electrically connect the package substrate 100 with the plurality of semiconductor chips 200.

The plurality of semiconductor chips 200 may exchange various signals with the package substrate 100 by the interposer 300, such as power signals (e.g., a driving voltage and a ground voltage), a control signal, and/or an input/output data signal, etc. The interposer 300 may include an interposer substrate, a redistribution structure, a penetrating electrode, and an interposer contact pad arranged on an upper surface of the interposer.

The interposer substrate may include a silicon wafer having silicon (Si), for example, crystalline silicon, polycrystalline silicon, or amorphous silicon. The interposer substrate may be planar, and may include upper and lower surfaces opposite to each other.

The redistribution structure may be arranged on the upper surface of the interposer substrate. The redistribution structure may include a wiring insulating layer covering the upper surface of the interposer substrate and a conductive redistribution pattern enclosed by the wiring insulating layer. For example, the redistribution structure may include a back-end-of-line (BEOL) structure. The wiring insulating layer may include an organic insulating material. For example, the wiring insulating layer may include a photo imageable dielectric (PID), such as polyimide.

The conductive redistribution pattern may include a plurality of wiring layers positioned at different levels in the wiring insulating layer to form a multi-layered structure, and conductive vias extending in a vertical direction in the wiring insulating layer to interconnect the plurality of wiring layers. For example, the conductive redistribution pattern may include at least one metal selected from tungsten (W), aluminum (Al), and copper (Cu). The conductive redistribution pattern may electrically connect a plurality of chip-interposer bump structures 310 with the penetrating electrode. Some of the conductive redistribution pattern, which are arranged on the upper surface of the redistribution structure, may be configured as interposer contact pads making contact with the chip-interposer bump structures 310, respectively. For example, the conductive pillars of the chip-interposer bump structures 310 may make contact with a portion of the conductive redistribution pattern, and the solder layer of the chip-interposer bump structure 310 may be extended between the conductive pillars and the chip pad of the semiconductor chip.

The penetrating electrode may vertically penetrate through the interposer substrate. The penetrating electrode may electrically connect the conductive redistribution pattern with the conductive bump pad of a substrate-interposer bump structure. The penetrating electrode may include a metal such as copper (Cu). A via insulating layer may be arranged between the penetrating electrode and the interposer substrate. The via insulating layer may include, for example, an oxide film, a nitride film, a carbide film, a polymer, or combinations thereof.

The interposer 300 and the plurality of semiconductor chips 200 may be electrically and physically connected with each other by at least one of the chip-interposer bump structures (that is, one or more chip-interposer bump structures interposed between the interposer and the plurality of semiconductor chips). An upper portion of the chip-interposer bump structure 310 may make contact with any one of the chip pads that are arranged on lower surfaces of the plurality of semiconductor chips 200, and a lower portion of the chip-interposer bump structure 310 may make contact with the interposer contact pad of the interposer.

The interposer 300 and the package substrate 100 may be electrically and physically connected by at least one of the substrate-interposer bump structures (that is, one or more substrate-interposer bump structures interposed between the interposer 300 and the package substrate 100). An upper portion of the substrate-interposer bump structure 320 may make contact with the interposer 300, and a lower portion of the substrate-interposer bump structure 320 may make contact with the upper contact pad 130 of the package substrate 100.

The plurality of passive elements 400 of the semiconductor package 10 may include a first passive element 410 and a second passive element 420. The first passive element 410 may be spaced apart from the interposer 300 in a first horizontal direction, and the second passive element 420 may be spaced apart from the interposer 300 in a second horizontal direction. The first horizontal direction may be substantially perpendicular to the second horizontal direction. The plurality of passive elements 400 may be arranged in such a configuration that the passive elements are spaced apart from four side surfaces of the interposer 300.

The plurality of passive elements 400 may be high and/or low voltage transistors, resistors and/or capacitors. For example, the passive element may include a multilayer ceramic capacitor (MLCC) or a low inductance ceramic capacitor (LICC). The plurality of passive elements 400 may be configured to apply a constant current to the plurality of semiconductor chips 200.

The first underfill layer 700 of the semiconductor package 10 may be provided between the interposer 300 and the package substrate 100. For example, the first underfill layer 700 may fill a gap space between the package substrate 100 and the interposer 300, so that the side surfaces of each substrate-interposer bump structure 320 may be covered with the first underfill layer 700. The first underfill layer 700 may be formed of an underfill material such as an epoxy resin.

A second underfill layer 710 may be provided between each of the plurality of semiconductor chips 200 and the interposer 300. For example, the second underfill layer 710 may fill a gap space between the interpose 300 and each of the first semiconductor chips 210, so that the side surfaces of each chip-interposer bump structure 310 may be covered with the second underfill layer 710. The chip-interposer underfill layer may be formed of an underfill material such as an epoxy resin. The second underfill layer 710 may be simultaneously formed in the process for forming the first underfill layer 700.

The first stiffener 500 of the semiconductor package 10 may be positioned on the package substrate 100. The lower surface of the first stiffener 500 may make contact with the package substrate 100. The first stiffener 500 may be attached to the upper surface 100_U of the package substrate 100 by an adhesive layer. The first stiffener 500 may include a metal such as steel or copper (Cu).

A stiffness of the first stiffener 500 may have a stiffness greater than a stiffness of the package substrate 100. The elastic modulus of the first stiffener 500 may be about 1.5 E2 kgf/cm² to about 3E3 kgf/cm². Although the stiffness is expressed as an elastic modulus, it is not limited thereto.

The first stiffener 500 may include a first hole 510 and a second hole 520. The first hole 510 may accommodate the interposer 300, and the second hole 520 may accommodate the plurality of passive elements 400. In some embodiments, the second hole 520 may include a hole in which the first passive element 410 is positioned and a hole in which the second passive element 420 is positioned. The second hole 520 may include a hole in which a series of the passive elements are entirely arranged.

The first hole 510 and the second hole 520 may penetrate through the first stiffener 500 in such a configuration that the first hole 510 and the second hole 520 extend from an upper surface to a lower surface of the first stiffener 500. In other words, in a plan view of the first stiffener 500, the first stiffener 500 may include a first hole 510 and a second hole 520 penetrating therethrough. FIG. 2 illustrates that the second holes 520 are positioned on each of the four sides of the first hole 510 in FIG. 21, which should not be construed as limited to the number or locations of the second holes 520. For example, two or more second holes 520 may be arranged on each side of the first hole 510.

The first stiffener 500 may include sidewalls defining the second hole 520. The plurality of passive elements 400 in the second hole 520 may be positioned between the sidewalls. The plurality of passive elements 400 may be surrounded by the sidewalls in the first horizontal direction and/or the second horizontal direction. Thus, the contamination to the passive elements from surroundings may be sufficiently prevented by the sidewalls. In some embodiments, the first underfill layer 700 filling the gap space between the interposer 300 and the package substrate 100 may be prevented from making contact with the passive elements 400 by the first stiffener 500.

The first stiffener 500 may also include sidewalls 511 defining the first hole 510. The interposer 300 in the first hole 510 may be positioned between the neighboring sidewalls 511. The sidewalls 511 defining the second hole 520 may include the sidewalls 511 defining the first hole 510. The first stiffener 500 may include the sidewalls positioned between the interposer 300 and the plurality of passive elements 400. In some embodiments, the sidewalls 511 of the first hole 510 may prevent the first underfill layer 700, which fills the gap space between the interposer 300 and the package substrate 100, from getting out of first hole 510. The first underfill layer 700 may be in contact with the sidewalls defining the first hole 510 of the first stiffener 500.

Thus, when performing a high speed underfill process for forming the first underfill layer 700, the underfill materials may be prevented from flowing toward the plurality of passive elements 400 by the first stiffener 500. That is, in the high-speed underfill process that a sufficient amount of the underfill materials is supplied and rapidly filled into the gap space between the interposer 300 and the package substrate 100, the passive elements 400 may be sufficiently prevented from staining with the underfill materials by the sidewalls 510 defining the first hole 510 and the second holes 520 (in other words, the sidewalls between the plurality of passive elements 400 and the interposer 300).

The first stiffener 500 may be attached onto the upper surface 100_U of the package substrate 100. The first stiffener 500 may be configured to mechanically support the package substrate 100, to improve mechanical safety of the semiconductor package 10. An area of the first stiffener 500 may be 20% to 40% of an area of the package substrate 100. The first stiffener 500 may cover four corners of the upper surface of the package substrate 100.

The second stiffener 600 of the semiconductor package 10 may be positioned on the first stiffener 500. A lower surface of the second stiffener 600 may be in contact with an upper surface of the first stiffener 500. The second stiffener 600 may be adhered to the upper surface of the first stiffener 500 by an adhesive layer. The second stiffener 600 may include a metal such as steel or copper (Cu).

A stiffness of the second stiffener 600 may have a greater stiffness than a stiffness of the package substrate 100. The elastic modulus of the second stiffener 600 may be about 1.5 E2 kgf/cm² to about 3E3 kgf/cm². Although the stiffness is expressed as an elastic modulus, it is not limited thereto.

The second stiffener 600 may include a third hole 610. The third hole 610 may communicate with the first hole 510. The second stiffener 600 may be arranged in such a configuration that the interposer 300 and the plurality of semiconductor chips 200 are not covered by the second stiffener 600. The second stiffener 600 might not overlap the interposer 300 and the plurality of semiconductor chips 200 in a vertical direction. In a plan view of the second stiffener 600, the second stiffener 600 may have a third hole 610 that penetrates through the second stiffener 600 and is located at the same position as the first hole 510 with the same size.

A total height of the first stiffener 500 and the second stiffener 600 may be about 500 μm to about 4000 μm. In some embodiments, the total height of the first stiffener 500 and the second stiffener 600 may be greater than the height summation of the interposer 300 and the plurality of semiconductor chips 200.

The first stiffener 500 may have a first coefficient of thermal expansion. The second stiffener 600 may have a second coefficient of thermal expansion. The second coefficient of thermal expansion may be different from the first coefficient of thermal expansion. In some embodiments, the coefficient of thermal expansion of the package substrate 100 may be greater than the first thermal expansion coefficient, and the first thermal expansion coefficient may be greater than the second thermal expansion coefficient. The closer the stiffener is positioned to the package substrate 100, the greater the coefficient of thermal expansion of the stiffener is relative to a stiffener positioned further from the package substrate 100.

The plurality of semiconductor chips 200 may be mounted on the interposer 300 having such a large area that the plurality of semiconductor chips 200 are sufficiently mounted. As the thickness of the large-area interposer 300 gets thinner and thinner, each coefficient of thermal expansion of the elements might increasingly not coincide with each other in the semiconductor package 10, which makes the warpage control increasingly difficult. The warpage defect caused by the difference in coefficients of thermal expansion between the elements can give rise to damages, such as cracks, to semiconductor packages, which reduces the reliability of the semiconductor packages.

The semiconductor package of an embodiment may mechanically support the package substrate 100 by the first stiffener 500, to thereby reduce and restrain the warpage defect caused by differences in coefficients of thermal expansion of the elements in the semiconductor package 10.

The semiconductor package 100 of an embodiment may include stiffeners having different coefficients of thermal expansion, such as the first stiffener 500 and the second stiffener 600, to restrain cracks from the semiconductor package 10 in reducing and restraining the warpage defect. That is, when a stiffener is installed in semiconductor packages, the warpage defect can be reduced, however, cracks may occur in the semiconductor package 10 in restraining the warpage defect. According to an embodiment, cracks occurring in restraining the warpage defect may be restrained by the stiffeners in which the coefficient of thermal expansion increases as the stiffener is in a position closer to the package substrate. The warpage defect of the package substrate 100 may be gradually restrained by the first stiffener 500 and the second stiffener 600, instead that the warpage defect is rapidly reduced, so that cracks are prevented from occurring in restraining the warpage defect.

For example, the first coefficient of thermal expansion may be 50% to 90% of the coefficient of thermal expansion of the package substrate 100. The second coefficient of thermal expansion may be 50% to 90% of the first coefficient of thermal expansion. For example, the first coefficient of thermal expansion and the second coefficient of thermal expansion may be about 7E-6/K to about 20E-6/K. Other coefficients of thermal expansion (and relative coefficient percentages) are also possible.

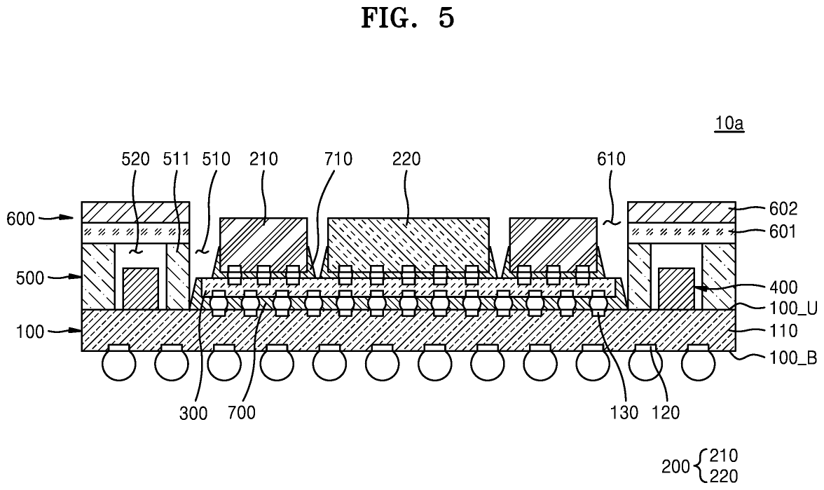

FIG. 5 is a cross-sectional view schematically illustrating a semiconductor package 10a according an embodiment.

Referring to FIG. 5, the semiconductor package 10a may include a package substrate 100, a plurality of semiconductor chips 200, an interposer 300, a plurality of passive elements 400, a first stiffener 500, and a second stiffener 600. Hereinafter, the same contents of the semiconductor package 10a in FIG. 5 as the semiconductor package 10 in FIG. 1 are omitted, and the differences between them are mainly described.

In some embodiments, the second stiffener 600 may include a plurality of layers 601 and 602. The plurality of layers 601 and 602 may have different coefficients of thermal expansion. In some embodiments, the coefficients of thermal expansion of the plurality of layers 601 and 602 of the second stiffener 600 may increase as the layers 601 and 602 gets closer to the first stiffener 500. In some embodiments, the second stiffener 600 may include the first layer 601 and the second layer 602 having different coefficients of thermal expansion. The coefficient of thermal expansion of the first layer 601 may be greater than that of the second layer 602. That is, a volume of the first layer 601 may expand more than that of the second layer 602 when the temperature rises, to thereby restrain cracks in the package substrate 100.

In the second stiffener 600 including a plurality of layers 601 and 602 according to an embodiment, when the semiconductor package is heated and the temperature rises, the thermal expansion of the second stiffener 600 gradually decreases as the second stiffener 600 is farther away from the package substrate 100. As the coefficient of thermal expansion is gradually reduced, cracks may be prevented in restraining the warpage defect.

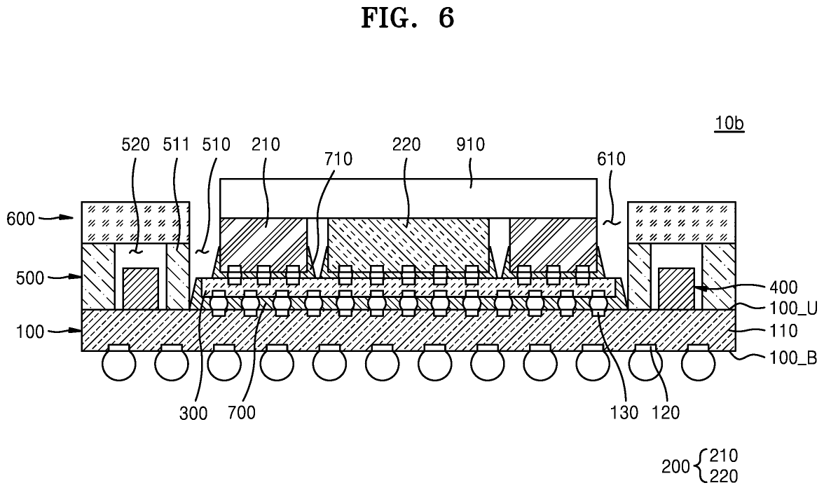

FIG. 6 is a cross-sectional view schematically illustrating a semiconductor package 10b according to an embodiment.

Referring to FIG. 6, the semiconductor package 10b may include a package substrate 100, a plurality of semiconductor chips 200, an interposer 300, a plurality of passive elements 400, a first stiffener 500, a second stiffener 600, and a heat sink 910. Hereinafter, the same contents of the semiconductor package 10b in FIG. 6 as the semiconductor package 10 in FIG. 1 are omitted, and the differences between them are mainly described.

The heat sink 910 of the semiconductor package 10b may be arranged on the plurality of semiconductor chips 200. The heat sink 910 may be configured to dissipate heat generated from the plurality of semiconductor chips 200. The heat sink 910 may include a thermally conductive material having high thermal conductivity. For example, the heat sink 910 may include a metal such as copper (Cu), aluminum (Al), etc., or a carbon-containing material such as graphene, graphite, carbon nanotubes, etc. However, the materials of the heat sink 910 are not limited to the materials described above. In an embodiment, the heat sink 910 may include a single metal layer or a plurality of stacked metal layers.

The plurality of semiconductor chips 200 may be attached to the heat sink 910 by a first thermal interface material (TIM) layer (not illustrated). The first TIM layer may include a thermally conductive and electrically insulating material. For example, the first TIM layer may include a polymer comprising a metal powder such as silver and copper, a thermal grease, a white grease, and combinations thereof. As the heat sink 910 make direct contact with the plurality of semiconductor chips 200 by the first TIM layer, the characteristics of heat dissipation may be improved.

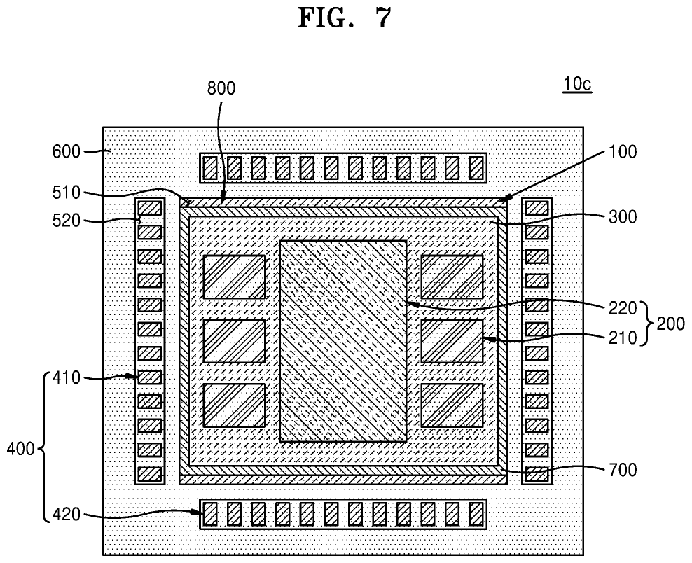

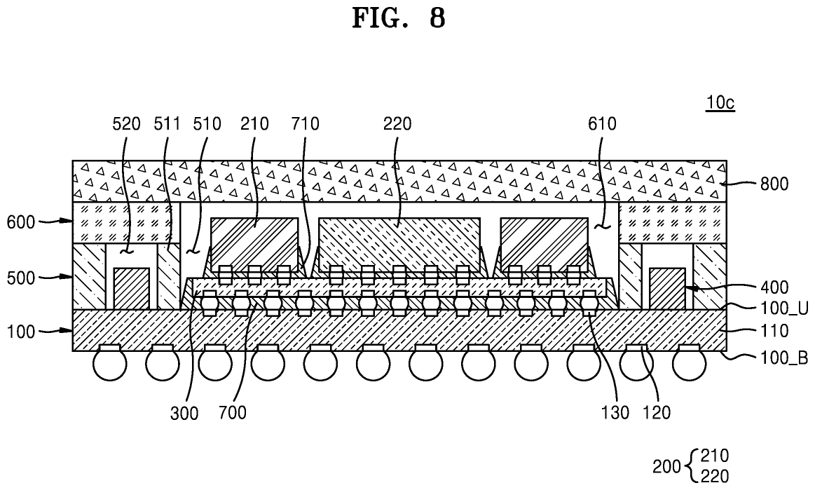

FIG. 7 is a plan view schematically illustrating a semiconductor package according to anther embodiment. FIG. 8 is a cross-sectional view schematically illustrating the semiconductor package in FIG. 7.

Referring to FIGS. 7 and 8, the semiconductor package 10c may include a package substrate 100, a plurality of semiconductor chips 200, an interposer 300, a plurality of passive elements 400, a first stiffener 500, a second stiffener 600, a first underfill layer 700, and a first plate 800.

Hereinafter, the same contents of the semiconductor package 10c in FIGS. 7 and 8 as the semiconductor package 10 in FIG. 1 are omitted, and the differences between them are mainly described.

The first plate 800 of the semiconductor package 10c may be arranged on the second stiffener 600. Each of upper and lower surfaces of the first plate 800 may be flat. The first plate 800 may cover the upper surface of the second stiffener 600 and the third hole 610. In other words, upper surfaces of the plurality of semiconductor chips 200 may be blocked from surroundings by the first plate 800.

The package substrate 100 of the semiconductor package 10c of an embodiment may be mechanically supported by the first plate 800, to thereby alleviate and restrain the warpage defect caused by the differences of coefficients of thermal expansion between the individual components of the semiconductor package 10.

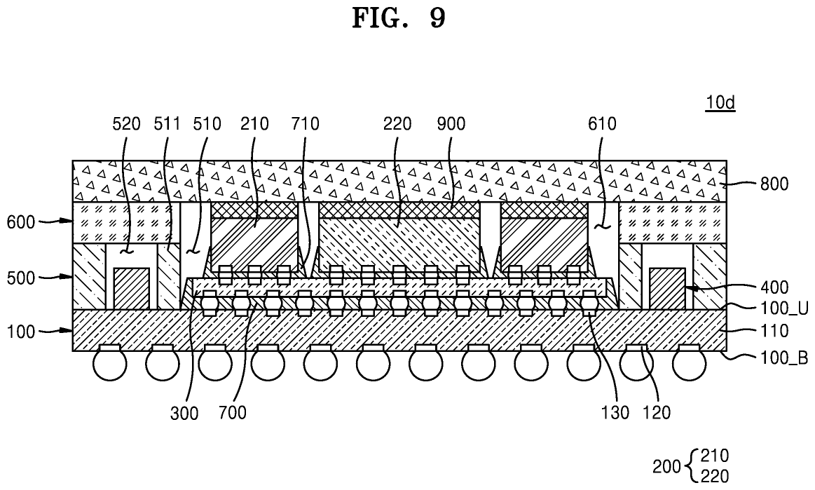

FIG. 9 is a cross-sectional view schematically illustrating a semiconductor package 10d according to an embodiment.

Referring to FIG. 9, the semiconductor package 10d may include a package substrate 100, a plurality of semiconductor chips 200, an interposer 300, a plurality of passive elements 400, a first stiffener 500, a second stiffener 600, a thermal interface material layer 900, and a first plate 800.

Hereinafter, the same contents of the semiconductor package 10d in FIG. 9 as the semiconductor package 10c in FIG. 8 are omitted, and the differences between them are mainly described.

The thermal interface material (TIM) layer 900 of the semiconductor package 10d may be arranged between the first plate 800 and the plurality of semiconductor chips 200. The TIM layer 900 may be arranged on the plurality of semiconductor chips 200. The TIM layer 900 may be attached to the upper surface of each plurality of semiconductor chips 200, to thereby improve the characteristics of heat dissipation.

In some embodiments, the TIM layer 900 may include a thermally conductive and electrically insulating material. For example, the TIM layer 900 may include a polymer comprising a metal powder such as silver and copper, a thermal grease, a white grease, and combinations thereof. Heat dissipation characteristics of the plurality of semiconductor chips 200 may be improved through the TIM layer 900.

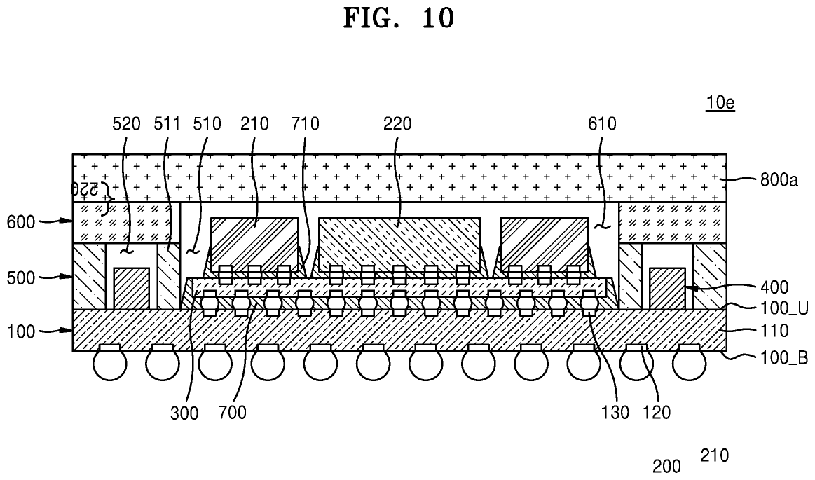

FIG. 10 is a cross-sectional view schematically illustrating a semiconductor package according to an embodiment.

Referring to FIG. 10, the semiconductor package 10e may include a package substrate 100, a plurality of semiconductor chips 200, an interposer 300, a plurality of passive elements 400, a first stiffener 500, a second stiffener 600, and a first plate 800a.

Hereinafter, the same contents of the semiconductor package 10e in FIG. 10 as the semiconductor package 10c in FIG. 8 are omitted, and the differences between them are mainly described.

The first plate 800a of the semiconductor package 10e may have a third coefficient of thermal expansion. The first plate 800a may have a third coefficient of thermal expansion different from the first coefficient of thermal expansion of the first stiffener 500 and the second coefficient of thermal expansion of the second stiffener 600.

In some embodiments, the third coefficient of thermal expansion may be less than the second coefficient of thermal expansion, the second coefficient of thermal expansion may be less than the first coefficient of thermal expansion, and the first coefficient of thermal expansion may be less than the coefficient of thermal expansion of the package substrate. The coefficient of thermal expansion may decrease more and more, as the structure is positioned away from the package substrate farther and farther.

When the temperature of the semiconductor package 10e of an embodiment rises, the thermal expansion of the structure may decrease more and more, as it is positioned away from the package substrate 100 farther and farther. As the coefficient of thermal expansion is gradually reduced, cracks may be prevented in restraining the warpage defect.

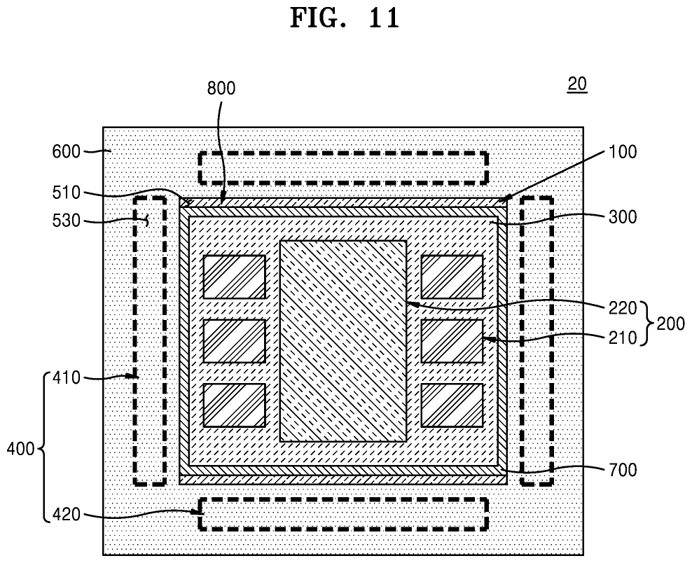

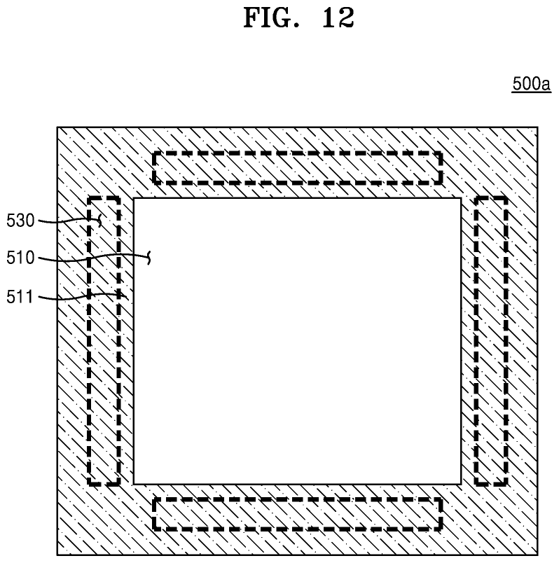

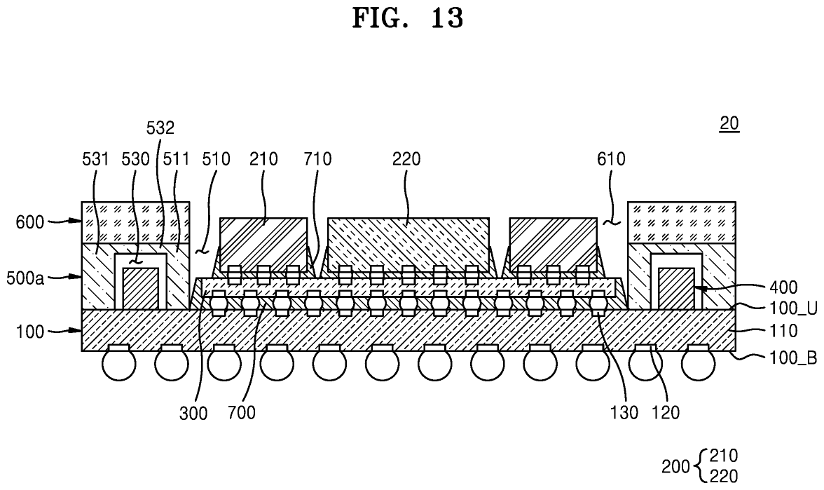

FIG. 11 is a plan view schematically illustrating a semiconductor package according to an embodiment. FIG. 12 is a plan view schematically illustrating a first stiffener of the semiconductor package in FIG. 11. FIG. 13 is a cross-sectional view schematically illustrating the semiconductor package in FIG. 11.

Referring to FIGS. 11 to 13, the semiconductor package 20 may include a package substrate 100, a plurality of semiconductor chips 200, an interposer 300, a plurality of passive elements 400, a first stiffener 500a, and a second stiffener 600. Hereinafter, the same contents of the semiconductor package 20 in FIGS. 11 to 13 as the semiconductor package 10 in FIG. 1 are omitted, and the differences between them are mainly described.

The first stiffener 500a of the semiconductor package 20 may be arranged on the package substrate 100. In other words, a lower surface of the first stiffener 500a may make contact with the package substrate 100. The first stiffener 500a may be attached to the upper surface 100_U of the package substrate 100 by an adhesive layer. The first stiffener 500a may include a metal, such as steel or copper (Cu).

The first stiffener 500a may include a first hole 510 and a first concave portion 530. The first hole 510 may accommodate the interposer 300, and the first concave portion 530 may accommodate the plurality of passive elements 400.

In some embodiments, the first concave portion 530 may include a concave portion for accommodating the first passive element 410 and a concave portion for accommodating the second passive element 420. The first concave portion 530 may include a concave portion for accommodating a plurality of passive elements arranged in a line at once. When the first stiffener 500a is viewed in a plan view in FIG. 12, the position of the first concave portion 530 is indicated by a dotted line.

The first stiffener 500a may include sidewalls 511 and 531 and an upper wall 532 for forming the first concave portion 530. The plurality of passive elements 400 accommodated in the first concave portion 530 may be positioned between the sidewalls 511 and 531. The plurality of passive elements 400 may be surrounded by the sidewalls 511 and 531 in a first horizontal direction and/or a second horizontal direction. The upper wall 532 may be spaced apart from the upper surfaces of the plurality of passive elements 400. The plurality of passive elements 400 may be blocked from surroundings by the upper wall 532. The plurality of passive elements 400 may be sealed by the sidewalls 531 and the top walls 532 of the first stiffener 500a and the package substrate 100.

Thus, the passive elements may be prevented from contamination from surroundings by the sidewalls 531. In some embodiments, the first underfill layer 700 interposed between the package substrate 100 and the interpose 300 may be prevented from making contact with the passive elements.

The first stiffener 500a may include the sidewalls 511 for forming the first hole 510. The interposer 300 in the first hole 510 may be arranged between the sidewalls 511. The first stiffener 500a may include the sidewalls 511 between the interposer 300 and the plurality of passive elements 400. In some embodiments, the sidewalls of the first hole 510 may prevent the first underfill layer 700, which fills a gap space between the interposer 300 and the package substrate 100, from getting out of the first hole 510. The first underfill layer 700 may be in contact with the sidewalls 511 of the first stiffener 500a for forming the first hole 510.

In performing a high-speed underfill process, the underfill may be prevented from flowing toward the passive elements by the first stiffener 500. In the high-speed underfill process of rapidly filling the gap space between the interposer 300 and the package substrate 100 by injecting a large amount of underfill, the underfill may be prevented from making contact with the passive elements 400 by the sidewalls 511 by which the first hole 510 and the first concave portion 530 are defined (the sidewalls between the interposer 300 and the passive elements 400). In addition, in the process of attaching the second stiffener 600 to an upper surface of the first stiffener 500, the upper surface of the first stiffener 500 may be sufficiently large, and thus, the second stiffener 600 may be easily attached to the first stiffener 500.

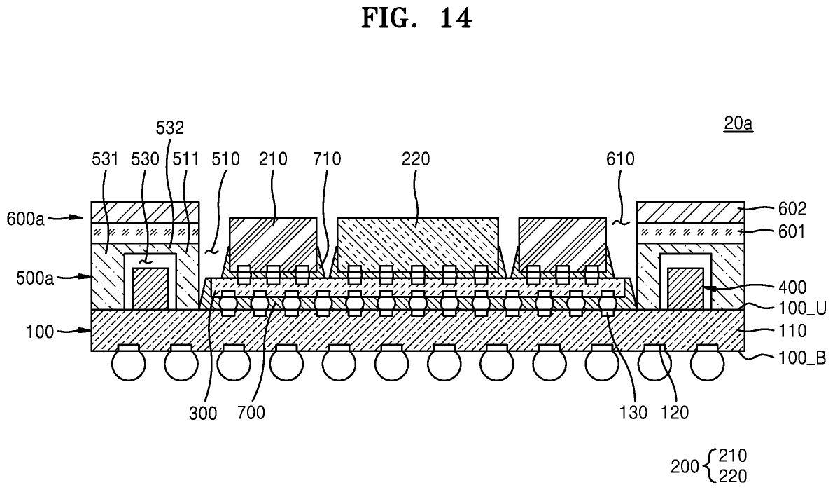

FIG. 14 is a cross-sectional view schematically illustrating a semiconductor package according to an embodiment.

Referring to FIG. 14, the semiconductor package 20a may include a package substrate 100, a plurality of semiconductor chips 200, an interposer 300, a plurality of passive elements 400, a first stiffener 500a, and a second stiffener 600.

Hereinafter, the same contents of the semiconductor package 20a in FIG. 14 as the semiconductor package 20 in FIG. 11 are omitted, and the differences between them are mainly described.

In some embodiments, the second stiffener 600 may include a plurality of layers 601 and 602. The plurality of layers 601 and 602 may have different coefficients of thermal expansion. In some embodiments, the coefficients of thermal expansion of the layers 601 and 602 in the second stiffener 600 may be greater as is closer to the first stiffener 500a. In some embodiments, the second stiffener 600 may include the first layer 601 and the second layer 602 having different coefficients of thermal expansion. The coefficient of thermal expansion of the first layer 601 may be greater than that of the second layer 602. That is, as a volume change rate to a temperature is greater in the first layer 601 than in the second layer 602, cracks may be restrained in the package substrate 100.

In the second stiffener 600 including a plurality of layers 601 and 602 according to an embodiment, when the semiconductor package is heated and the temperature rises, the thermal expansion of the second stiffener 600 gradually decreases as the second stiffener 600 is farther away from the package substrate 100. As the coefficient of thermal expansion is gradually reduced, cracks may be prevented in restraining the warpage defect.

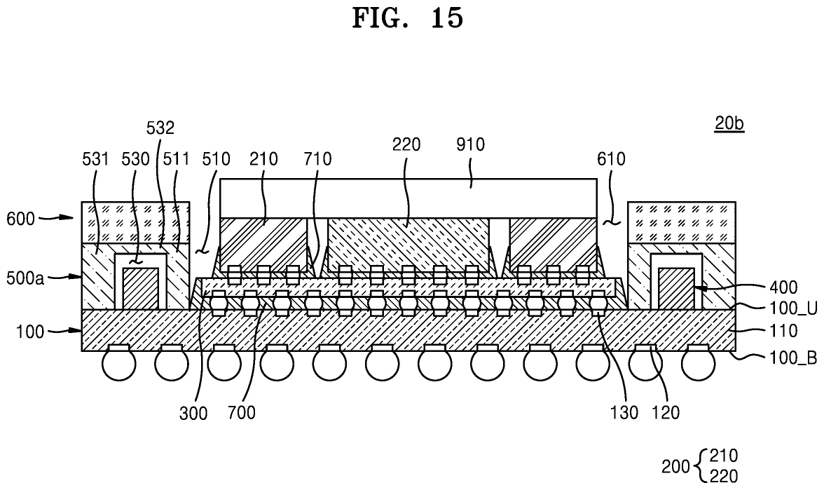

FIG. 15 is a cross-sectional view schematically illustrating a semiconductor package according to an embodiment.

Referring to FIG. 15, the semiconductor package 20b may include a package substrate 100, a plurality of semiconductor chips 200, an interposer 300, a plurality of passive elements 400, a first stiffener 500a, a second stiffener 600, and a heat sink 910.

Hereinafter, the same contents of the semiconductor package 20b in FIG. 15 as the semiconductor package 20 in FIG. 11 are omitted, and the differences between them are mainly described.

The heat sink 910 of the semiconductor package 20b may be arranged on the plurality of semiconductor chips 200. The heat sink 910 may be configured to dissipate the heat generated from the plurality of semiconductor chips 200. The heat sink 910 may include a thermally conductive material having high thermal conductivity. For example, the heat sink 910 may include a metal such as copper (Cu), aluminum (Al), etc., or a carbon-containing material such as graphene, graphite, and/or carbon nanotubes. However, the material of the heat sink 910 is not limited to the materials described above. In an embodiment, the heat sink 910 may include a single metal layer or a plurality of stacked metal layers.

The plurality of semiconductor chips 200 may be attached to the heat sink 910 by a first thermal interface material (TIM) layer (not illustrated). The first TIM layer may include a thermally conductive and electrically insulating material. For example, the first TIM layer may include a polymer including a metal powder such as silver and copper, a thermal grease, a white grease, and combinations thereof. As the heat sink 910 may make direct contact with the plurality of semiconductor chips 200 by the first TIM layer, the characteristics of heat dissipation may be improved.

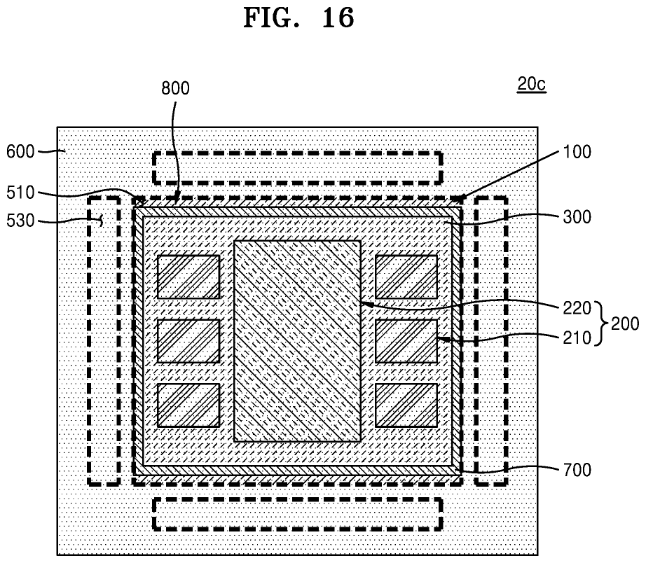

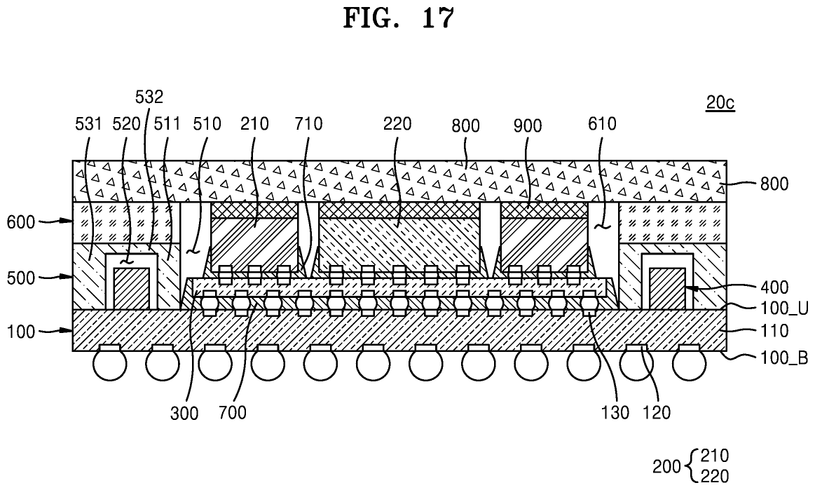

FIG. 16 is a plan view schematically illustrating a semiconductor package according to an embodiment. FIG. 17 is a cross-sectional view schematically illustrating a semiconductor package according to an embodiment.

Referring to FIGS. 16 to 17, the semiconductor package 20c may include a package substrate 100, a plurality of semiconductor chips 200, an interposer 300, a plurality of passive elements 400, a first stiffener 500a, a second stiffener 600, a first underfill layer 700, a first plate 800, and a thermal interface material layer 900.

Hereinafter, the same contents of the semiconductor package 20c in FIGS. 16 and 17 as the semiconductor package 20 in FIG. 11 are omitted, and the differences between them are mainly described.

The first plate 800 of the semiconductor package 20c may be arranged on the second stiffener 600. Each of upper and lower surfaces of the first plate 800 may be flat. The first plate 800 may cover the upper surface of the second stiffener 600 and the third hole 610. In other words, upper surfaces of the plurality of semiconductor chips 200 may be blocked from surroundings by the first plate 800.

The thermal interface material (TIM) layer 900 of the semiconductor package 20c may be arranged between the first plate 800 and the plurality of semiconductor chips 200. The TIM layer 900 may be arranged on the plurality of semiconductor chips 200. The TIM layer 900 may be attached to the upper surface of each of the plurality of semiconductor chips 200, to thereby improve the characteristics of heat dissipation.

In some embodiments, the TIM layer 900 may include a thermally conductive and electrically insulating material. For example, the TIM layer 900 may include a polymer including a metal powder such as silver and copper, a thermal grease, a white grease, and combinations thereof. The characteristics of heat dissipation of the semiconductor chips 200 may be improved by the TIM layer 900.

The package substrate 100 of the semiconductor package 20c of an embodiment may be mechanically supported by the first plate 800, to thereby alleviate and restrain the warpage defect caused by the differences of coefficients of thermal expansion between the individual components of the semiconductor package 20c.

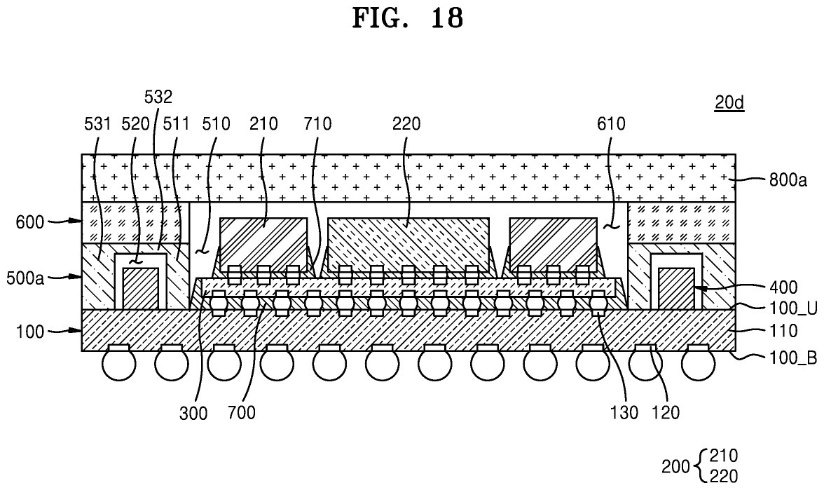

FIG. 18 is a cross-sectional view schematically illustrating a semiconductor package according to an embodiment.

Referring to FIG. 18, the semiconductor package 20d may include a package substrate 100, a plurality of semiconductor chips 200, an interposer 300, a plurality of passive elements 400, a first stiffener 500, a second stiffener 600, and a first plate 800a.

Hereinafter, the same contents of the semiconductor package 20d in FIG. 18 as the semiconductor package 20c in FIG. 17 are omitted, and the differences between them are mainly described.

The first plate 800a of the semiconductor package 20d may have a third coefficient of thermal expansion. The first plate 800a may have a third coefficient of thermal expansion different from the first coefficient of thermal expansion of the first stiffener 500 and the second coefficient of thermal expansion of the second stiffener 600.

In some embodiments, the third coefficient of thermal expansion may be less than the second coefficient of thermal expansion, the second coefficient of thermal expansion may be less than the first coefficient of thermal expansion, and the first coefficient of thermal expansion may be less than the coefficient of thermal expansion of the package substrate 100. The coefficient of thermal expansion may decrease more and more, as is away from the package substrate farther and farther.

When the temperature of the semiconductor package 20d of an embodiment rises up, the thermal expansion may decrease more and more, as is away from the package substrate 100 farther and farther. As the coefficient of thermal expansion is gradually reduced, cracks may be prevented in restraining the warpage defect.

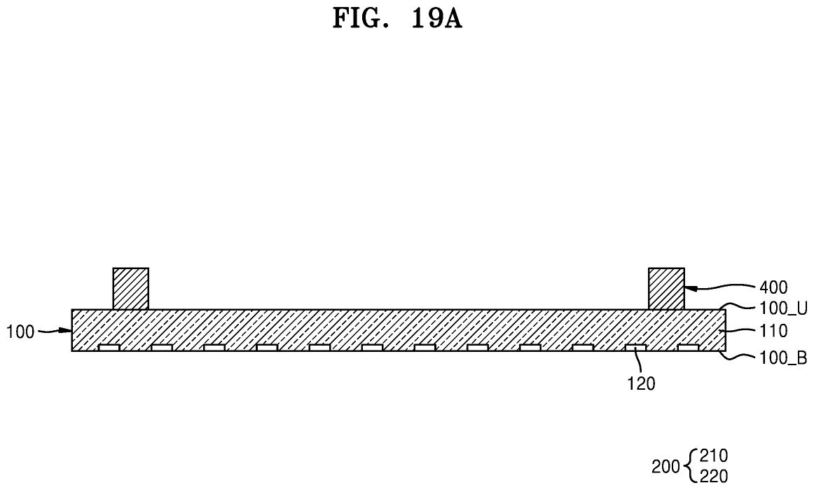

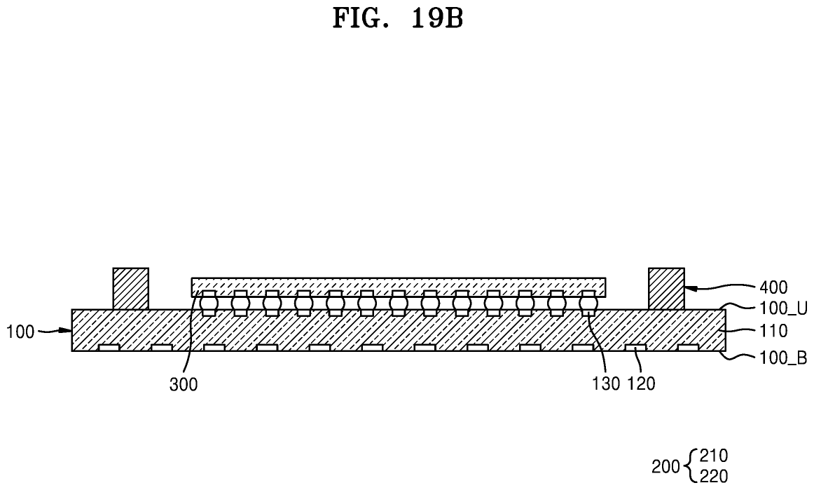

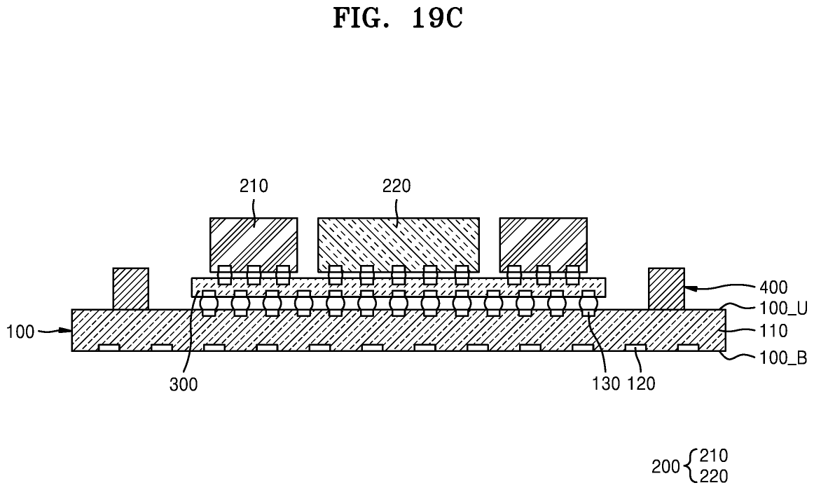

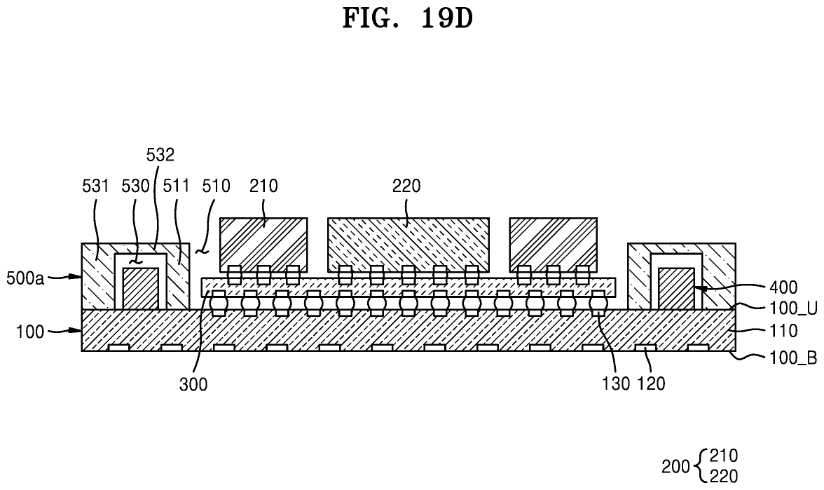

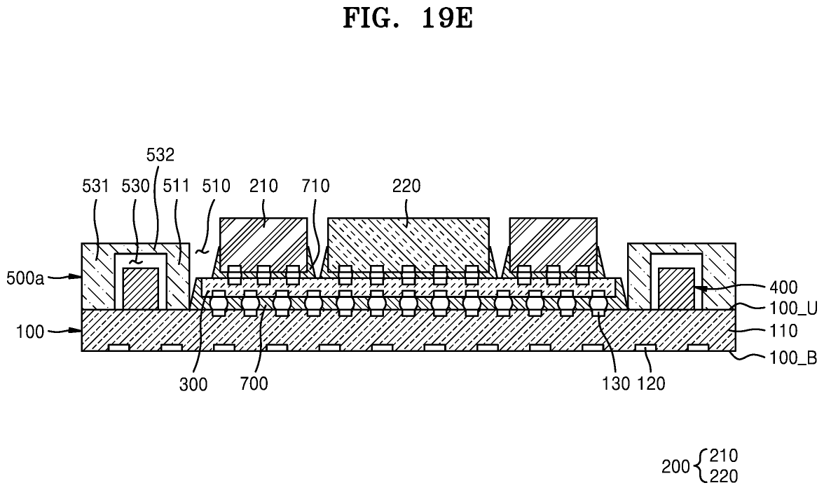

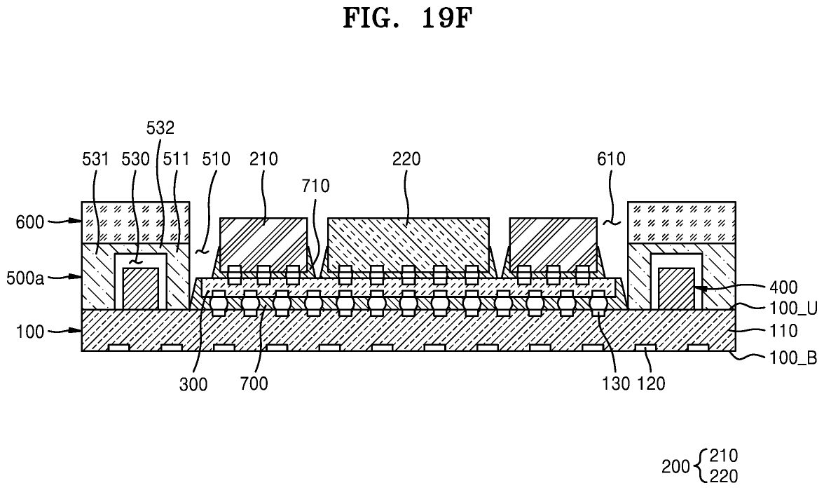

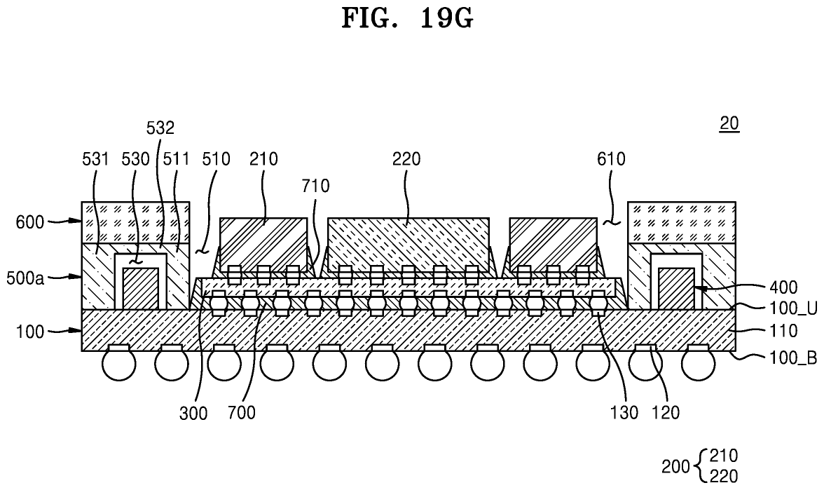

FIGS. 19A to 19G are cross-sectional views sequentially illustrating a method of manufacturing a semiconductor package according to an embodiment.

FIG. 19A illustrates a process of mounting a plurality of passive devices 400 on the package substrate 100. FIG. 19B illustrates a process of positioning the interposer 300 on the package substrate 100. The interposer 300 and the package substrate 100 may be electrically and physically connected by at least one of the substrate-interposer bump structures. An upper portion of the substrate-interposer bump structure may contact the interposer 300, and a lower portion of the substrate-interposer bump structure may contact an upper contact pad 130 of the package substrate 100.

FIG. 19C illustrates a process of mounting a plurality of semiconductor chips 200 on the interposer 300. The plurality of semiconductor chips 200 may be mounted on the interposer 300 by a flip-chip process. In some embodiments, the interposer 300 and the plurality of semiconductor chips 200 may be electrically and physically connected by at least one of chip-interposer bump structures. An upper portion of the chip-interposer bump structure may be in contact with any one of chip pads that are arranged on lower surfaces of the semiconductor chips 200, and a lower portion of the chip-interposer bump structure may be in contact with an interposer contact pad of the interposer 300.

FIG. 19D illustrates a process of forming a first stiffener 500a on the package substrate 100. The first stiffener 500a may be formed in such a configuration that a first hole 510 accommodates the interposer 300 and a first concave portion 530 accommodates a plurality of passive elements 400. The first stiffener 500a may be attached on the package substrate 100, and the sidewalls 511 for defining the first hole 510 may be positioned between the interposer 300 and the plurality of passive elements 400.

FIG. 19E illustrates a process of forming a first underfill layer 700 and a second underfill layer 710. The first underfill layer 700 may be formed by filling a gap space between the package substrate 100 and the interposer 300, and the second underfill layer 710 may be formed by filling a gap space between the interposer 300 and the plurality of semiconductor chips 200. In the underfill process, the first underfill layer 700 and the second underfill layer 710 may be simultaneously formed.

In a high-speed underfill process, underfill materials of the first underfill layer 700 and the second underfill layer 710 may flow toward an outside of the interposer 300 or the plurality of semiconductor chips 200. In case of the semiconductor package of an embodiment, although flowing toward the outside of the interposer 300 or the semiconductor chips 200, the underfill materials may make contact with the first stiffener 500a and be prevented from making contact with the passive elements 400 by the first stiffener 500a.

FIG. 19F illustrates a process of forming the second stiffener 600 on the first stiffener 500a. The second stiffener 600 may include a third hole 610 communicating with the first hole 510. The second stiffener 600 may be formed on the first stiffener 500 in such a configuration that the third hole 610 communicates with the first hole 510. The second stiffener 600 may be adhered and secured onto a whole upper surface of the first stiffener 500a having the first hole 510.

FIG. 19G illustrates a process of attaching external contact terminals to lower contact pads 120 of the package substrate 100. The external contact terminals may electrically and physically connect the package substrate 100 to an external device. The external contact terminals may be formed from, for example, solder balls or solder bumps.

Up to now, the inventive concept has been described with reference to the embodiment shown in the drawings, but this is only exemplary, and it will be understood by those skilled in the art that various modifications and equivalent other embodiments are possible therefrom. Therefore, the true technical protection scope of the inventive concept should be determined by the technical spirit of the appended claims.

While the inventive concept has been particularly shown and described with reference to embodiments thereof, it will be understood that various changes in form and details may be made therein without departing from the spirit and scope of the following claims.

What is claimed is:

1. A semiconductor package, comprising: a package substrate;
a plurality of semiconductor chips mounted on the package substrate;
an interposer arranged between the package substrate and the plurality of semiconductor chips;
a plurality of passive elements mounted on the package substrate and spaced apart from the interposer;
a first stiffener positioned on the package substrate and including a first hole accommodating the interposer and a second hole accommodating the plurality of passive elements; and
a second stiffener positioned on the first stiffener and including a third hole communicating with the first hole,
wherein
the first stiffener has a first coefficient of thermal expansion, and
the second stiffener has a second coefficient of thermal expansion different from the first coefficient of thermal expansion.

2. The semiconductor package of claim 1, wherein
a coefficient of thermal expansion of the package substrate is greater than the first coefficient of thermal expansion, and
the first coefficient of thermal expansion is greater than the second coefficient of thermal expansion.

3. The semiconductor package of claim 1, wherein
the second stiffener includes a plurality of layers having different coefficients of thermal expansion.

4. The semiconductor package of claim 3, wherein
coefficients of thermal expansion of the layers of the second stiffener increase as the layers are closer to the first stiffener.

5. The semiconductor package of claim 1, wherein
a sum of heights of the first stiffener and the second stiffener is about 500 μm to about 4000 μm.

6. The semiconductor package of claim 1, further comprising
a first underfill layer between the package substrate and the interposer,
the first underfill layer being in contact with sidewalls defining the first hole of the first stiffener.

7. The semiconductor package of claim 1, further comprising
a first plate positioned on the second stiffener and covering an upper surface of the second stiffener and the third hole.

8. The semiconductor package of claim 7, wherein
the first plate has a third coefficient of thermal expansion, and
the third coefficient of thermal expansion is different from the first coefficient of thermal expansion and the second coefficient of thermal expansion.

9. The semiconductor package of claim 8, wherein
the first coefficient of thermal expansion is smaller than a coefficient of thermal expansion of the package substrate,
the second coefficient of thermal expansion is smaller than the first coefficient of thermal expansion, and
the third coefficient of thermal expansion is smaller than the second coefficient of thermal expansion.

10. The semiconductor package of claim 7, further comprising
a thermal interface material layer between the first plate and the plurality of semiconductor chips.

11. A semiconductor package, comprising:
a package substrate;
a plurality of semiconductor chips mounted on the package substrate;
an interposer arranged between the package substrate and the plurality of semiconductor chips;
a plurality of passive elements mounted on the package substrate and spaced apart from the interposer;
a first stiffener positioned on the package substrate and including a first hole accommodating the interposer and a first concave portion surrounding the plurality of passive elements; and
a second stiffener positioned on the first stiffener and including a third hole communicating with the first hole,
wherein
the first stiffener has a first coefficient of thermal expansion, and
the second stiffener has a second coefficient of thermal expansion different from the first coefficient of thermal expansion.

12. The semiconductor package of claim 11, wherein
a sidewall defining the first hole is positioned between the interposer and the plurality of passive elements, and
a sidewall defining the first concave portion is spaced apart from side surfaces of the plurality of passive elements, and an upper wall defining the first concave portion is spaced apart from an upper surface of the plurality of passive elements.

13. The semiconductor package of claim 12, further comprising
a first underfill layer positioned between the package substrate and the interposer,
wherein
the first underfill layer is in contact with the sidewall of the first hole without any contact with the plurality of passive elements.

14. The semiconductor package of claim 11, wherein
the plurality of passive elements are positioned between sidewalls of the first concave portion of the first stiffener, and are not exposed to the outside by an upper wall of the first concave portion, and
the interposer and the plurality of semiconductor chips are exposed to the outside.

15. The semiconductor package of claim 11, wherein
a coefficient of thermal expansion of the package substrate is greater than the first coefficient of thermal expansion, and
the first coefficient of thermal expansion is greater than the second coefficient of thermal expansion.

16. The semiconductor package of claim 11, wherein
the second stiffener includes a plurality of layers having different coefficients of thermal expansion.

17. The semiconductor package of claim 16, wherein
coefficients of thermal expansion of the layers of the second stiffener increase as the layers are closer to the first stiffener.

18. The semiconductor package of claim 11, further comprising
a heat sink on the plurality of semiconductor chips.

19. The semiconductor package of claim 11, further comprising
a first plate positioned on the second stiffener to cover an upper surface of the second stiffener and the third hole, and having a third coefficient of thermal expansion,
wherein
the first coefficient of thermal expansion is smaller than a coefficient of thermal expansion of the package substrate,
the second coefficient of thermal expansion is smaller than the first coefficient of thermal expansion, and
the third coefficient of thermal expansion is smaller than the second coefficient of thermal expansion.

20. A semiconductor package, comprising:
a package substrate;
a plurality of semiconductor chips mounted on the package substrate;
an interposer arranged between the package substrate and the plurality of semiconductor chips;
a plurality of passive elements including a first passive element spaced apart from the interposer in a first horizontal direction and a second passive element spaced apart in a second horizontal direction;
a first stiffener positioned on the package substrate and including a first hole accommodating the interposer and a first concave portion surrounding the plurality of passive elements;
a second stiffener positioned on the first stiffener and including a third hole communicating with the first hole;
a first plate positioned on the second stiffener and covering an upper surface of the second stiffener and the third hole;
a first underfill layer positioned between the package substrate and the interposer and in the first hole of the first stiffener; and
a thermal interface material layer arranged between the first plate and the plurality of semiconductor chips,
wherein
the first stiffener has a first coefficient of thermal expansion smaller than that of the package substrate,
the second stiffener has a second coefficient of thermal expansion smaller than the first coefficient of thermal expansion,
the first plate has a third coefficient of thermal expansion smaller than the second coefficient of thermal expansion,
the first hole includes a sidewall positioned between the interposer and the plurality of passive elements,
the first concave portion includes sidewalls spaced apart from side walls of the plurality of passive elements and an upper surface spaced apart from upper surfaces of the plurality of passive elements,
a sum of heights of the first stiffener and the second stiffener is about 500 μm to about 4000 μm.
